(19) United States
(12) Patent Application Publication
(10) Pub. No.: US 2019/0035858 A1
(43) Pub. Date: Jan. 31, 2019

(54) TOUCH ARRAY SUBSTRATE AND TOUCH PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventors: Shuang LI, Wuhan, Hubei (CN); Jian-hong LIN, Wuhan, Hubei (CN)

(21) Appl. No.: 15/735,619

(22) PCT Filed: Sep. 6, 2017
(86) PCT No.: PCT/CN2017/100698

§ 371 Date: Dec. 12, 2017

(30) Foreign Application Priority Data
Jul. 25, 2017 (CN) 201710612071.0

(51) Int. Cl. H01L 27/32; H01L 51/52; G06F 3/041

(52) U.S. Cl. CPC H01L 27/323; G06F 3/041; H01L 51/5225; H01L 27/3244

(57) ABSTRACT

A touch array substrate and a touch panel are provided and the touch array substrate has a substrate, an organic electroluminescent pixel unit layer disposed on the substrate, wherein the organic electroluminescent pixel unit layer has an anode layer, a light emitting layer, and a cathode layer, all of which are stacked in sequence. The cathode layer consists of a plurality of sub-cathodes disposed at intervals, and the sub-cathodes are electrically connected to each other.

### FIELD OF THE DISCLOSURE

The present disclosure relates to the technical field of touch displays, and more particularly to a touch array substrate and a touch panel.

### BACKGROUND OF THE DISCLOSURE

People are paying increasing attention to active-matrix organic light emitting diodes (AMOLED) due to their advantages of high contrast, wide viewing angles, flexibility, etc. Conventional AMOLED panels, equipped with touch sensing structures, can constitute touch panels.

For conventional AMOLED panels, an array circuit layer is generally formed on a substrate. The array circuit layer provides an anode for pixels, and then a light emitting layer is formed on the array circuit layer. Finally, a cathode layer is formed on the light emitting layer. For AMOLED panels equipped with touch sensing structures, after a protective layer is formed on the cathode layer, a touch sensing layer is then formed on the protective layer. However, the cathode layer is generally formed using a large area depositing manner, and a relatively large capacitive load is easily induced by the cathode layer and the touch sensing layer, which affects touch sensing of touch panels.

As a result, it is necessary to provide a touch array substrate and a touch panel to solve the problems existing in the conventional technologies.

### SUMMARY OF THE DISCLOSURE

An object of the present disclosure is to provide a touch array substrate and a touch panel, which can effectively reduce a capacitive load induced by a cathode layer and a touch sensing layer to improve a touch sensing.

The present disclosure provides a touch array substrate including:
a substrate;
an organic electroluminescent pixel unit layer disposed on the substrate; wherein the organic electroluminescent pixel unit layer includes an anode layer, a light emitting layer, and a cathode layer, all of which are stacked in sequence;
wherein the cathode layer consists of a plurality of sub-cathodes disposed at intervals, and the sub-cathodes are electrically connected to each other;
wherein the sub-cathodes are in an array arrangement, and each of the sub-cathodes has a same shape and a same size; and
wherein the sub-cathodes are electrically connected to each other by a plurality of metal wires.

In the touch array substrate of the present disclosure, neighboring sub-cathodes in a same row are electrically connected to each other by the metal wires, and neighboring sub-cathodes in at least one column are electrically connected to each other by the metal wires.

In the touch array substrate of the present disclosure, neighboring sub-cathodes in a same column are electrically connected to each other by the metal wires, and neighboring sub-cathodes in at least one row are electrically connected to each other by the metal wires.

In the touch array substrate of the present disclosure, the substrate is a single-crystal silicon substrate or a polycrystalline silicon substrate.

In the touch array substrate of the present disclosure, the light emitting layer includes a hole injection layer, a hole transport layer, an organic light emitting layer, an electron transport layer, and an electron injection layer disposed in sequence and located at a side of the anode layer neighboring the cathode layer.

In the touch array substrate of the present disclosure, the touch array substrate further includes a protective layer and a touch sensing layer disposed in sequence and located on the cathode layer, wherein the touch sensing layer includes: a plurality of touch electrodes; and a plurality of touch signal wires, wherein each of touch signal wires is connected correspondingly with each of the touch electrodes.

In the touch array substrate of the present disclosure, the touch array substrate further includes an array circuit layer formed on the substrate, wherein the array circuit layer includes a plurality of thin-film transistors, and an active region is formed on the substrate.

The present disclosure further provides a touch array substrate, including:
a substrate;
an organic electroluminescent pixel unit layer disposed on the substrate; wherein the organic electroluminescent pixel unit layer includes an anode layer, a light emitting layer, and a cathode layer, all of which are stacked in sequence; and
wherein the cathode layer consists of a plurality of sub-cathodes disposed at intervals, and the sub-cathodes are electrically connected to each other.

In the touch array substrate of the present disclosure, the sub-cathodes are in an array arrangement, and each of the sub-cathodes has a same shape and a same size.

In the touch array substrate of the present disclosure, the sub-cathodes are electrically connected to each other by a plurality of metal wires.

In the touch array substrate of the present disclosure, neighboring sub-cathodes in a same row are electrically connected to each other by the metal wires, and neighboring sub-cathodes in at least one column are electrically connected to each other by the metal wires.

In the touch array substrate of the present disclosure, neighboring sub-cathodes in a same column are electrically connected to each other by the metal wires, and neighboring sub-cathodes in at least one row are electrically connected to each other by the metal wires.

In the touch array substrate of the present disclosure, the substrate is a single-crystal silicon substrate or a polycrystalline silicon substrate.

In the touch array substrate of the present disclosure, the light emitting layer includes a hole injection layer, a hole transport layer, an organic light emitting layer, an electron transport layer, and an electron injection layer disposed in sequence and located at a side of the anode layer neighboring the cathode layer.

In the touch array substrate of the present disclosure, the touch array substrate further includes a protective layer and a touch sensing layer disposed in sequence and located on the cathode layer, wherein the touch sensing layer includes: a plurality of touch electrodes; and a plurality of touch signal wires, wherein each of touch signal wires is connected correspondingly with each of the touch electrodes.

In the touch array substrate of the present disclosure, the touch array substrate further includes an array circuit layer formed on the substrate, wherein the array circuit layer includes a plurality of thin-film transistors, and an active region is formed on the substrate.

According to the above object of the present disclosure, a touch panel is further provided and includes:

a touch array substrate, including:
a substrate;
an organic electroluminescent pixel unit layer disposed on the substrate, wherein the organic electroluminescent pixel unit layer includes an anode layer, a light emitting layer, and a cathode layer, all of which are stacked in sequence; and
wherein the cathode layer consists of a plurality of sub-cathodes disposed at intervals, and the sub-cathodes are electrically connected to each other.

In the touch panel of the present disclosure, the sub-cathodes are in an array arrangement, and each of the sub-cathodes has a same shape and a same size.

In the touch panel of the present disclosure, the sub-cathodes are electrically connected to each other by a plurality of metal wires.

In the touch array substrate and the touch panel of the present disclosure, an area of the cathode layer is reduced by forming the cathode layer as a structure with a plurality of sub-cathodes which have intervals and are electrically connected to each other, so as to reduce a capacitive load between the cathode layer and a touch sensing layer and improve a touch sensing of the touch panel.

To make the above description of the present disclosure more clearly comprehensible, it is described in detail below in examples of preferred embodiments with the accompanying drawings.

### DESCRIPTION OF THE DRAWINGS

The technical aspects of the present disclosure and other advantageous effects will be apparent from the following detailed description of specific embodiments of the present disclosure taken in conjunction with the accompanying drawings.

FIG. 1 is a structural schematic diagram of a touch array substrate of a preferred embodiment of the present disclosure.

FIG. 2 is a first structural schematic diagram of a cathode layer of a touch array substrate of a preferred embodiment of the present disclosure.

FIG. 3 is a second structural schematic diagram of a cathode layer of a touch array substrate of a preferred embodiment of the present disclosure.

### DETAILED DESCRIPTION OF THE PREFERRED EMBODIMENTS

In order to further illustrate the technical means and the effects of the present disclosure, the following will be described in detail with reference to the preferred embodiments of the present disclosure and its accompanying drawings. The described embodiments are merely part of the present disclosure, and are not all embodiments. All other embodiments obtained by those of ordinary skill in the art, based on the embodiments in the present disclosure, without making creative work are within the scope of the present disclosure.

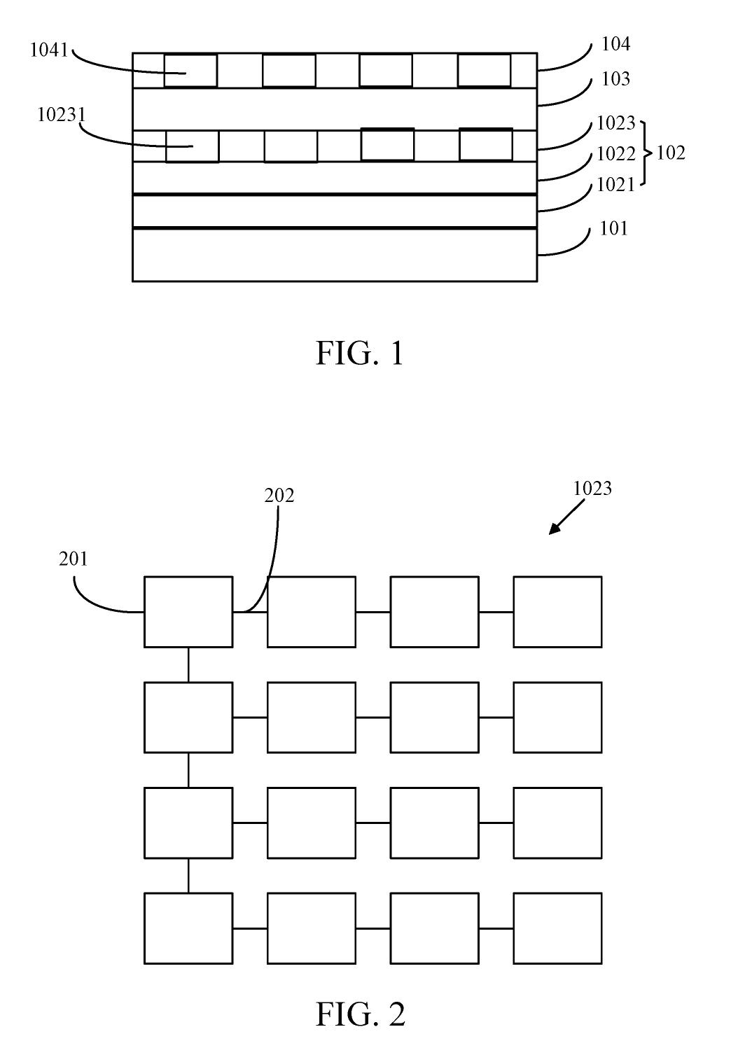

Refer to FIG. 1, which is a structural schematic diagram of a touch array substrate of a preferred embodiment of the present disclosure. As shown in FIG. 1, the touch array substrate provided by a preferred embodiment of the present disclosure includes a substrate 101, an organic electroluminescent pixel unit layer 102 disposed on the substrate 101, a protective layer 103 disposed on the organic electroluminescent pixel unit layer 102, and a touch sensing layer 104 disposed on the protective layer 103. The organic electroluminescent pixel unit layer 102 includes an anode layer 1021, a light emitting layer 1022, and a cathode layer 1023, all of which are stacked in sequence. The cathode layer 1023 consists of a plurality of sub-cathodes 10231 disposed at intervals, and the sub-cathodes 10231 are electrically connected to each other.

Further, the touch sensing layer 104 includes a plurality of touch electrodes 1041, and a plurality of touch signal wires (not shown), wherein each of the touch signal wires is connected correspondingly with each of the touch electrodes 1041. The present disclosure reduces an area of the cathode layer 1023 by dividing the cathode layer 1023 into the plurality of sub-cathodes 10231 electrically connected to each other, to reduce a capacitive load between the cathode layer 1023 and the touch sensing layer 104 and improve touch sensing of the touch panel.

Specifically, refer to FIG. 2, which is a first structural schematic diagram of a cathode layer of a touch array substrate of a preferred embodiment of the present disclosure. As shown in FIG. 2, the cathode layer 1023 includes a plurality of sub-cathodes 201 disposed at intervals, wherein the sub-cathodes 201 are in an array arrangement, and each of the sub-cathodes 201 has a same shape and a same size. Further, the sub-cathodes 201 can further be circular, elliptical, regular hexagonal, triangular, etc. The shape of the sub-cathodes 201 is not limited thereto.

Further, the sub-cathodes 201 are electrically connected to each other by a plurality of metal wires 202. It is to be noted that in a row direction, the neighboring sub-cathodes 201 in a same row are electrically connected by the metal wires 202, and in a column direction, it is only necessary to ensure that the neighboring sub-cathodes 201 in at least one column are electrically connected by the metal wires 202. As shown in FIG. 2, the neighboring sub-cathodes 201 in each of the rows are connected to each other by the metal wires 202, and the neighboring sub-cathodes 201 in a first column are connected to each other by the metal wires 202, so as to connect each of the sub-cathodes 201 in the cathode layer 1023 to each other and reduce the number of signal lines required for inputting signals into the cathode layer.

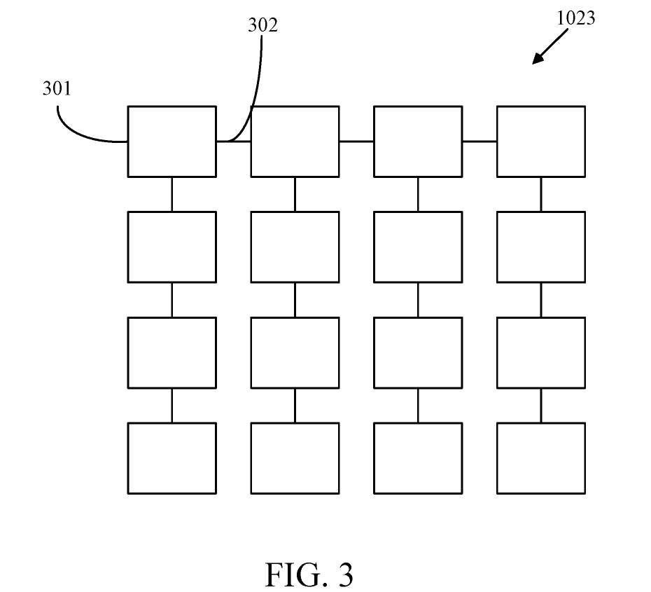

Refer to FIG. 3, which is a second structural schematic diagram of a cathode layer of a touch array substrate of a preferred embodiment of the present disclosure. As shown in FIG. 3, the cathode layer 1023 includes a plurality of sub-cathodes 301 disposed at intervals, wherein the sub-cathodes 301 are in an array arrangement, and each of the sub-cathodes 301 has a same shape and a same size. Further, the sub-cathodes 301 can further be circular, elliptical, regular hexagonal, triangular, etc. The shape of the sub-cathodes 301 is not limited thereto.

Further, the sub-cathodes 301 are electrically connected to each other by a plurality of metal wires 302. It is to be noted that in a column direction, the neighboring sub-cathodes 301 in a same column are electrically connected by the metal wires 302, and in a row direction, it is only necessary to ensure that the neighboring sub-cathodes 301 in at least one row are electrically connected by the metal wires 302. As shown in FIG. 2, the neighboring sub-cathodes 301 in each of the columns are connected to each other by the metal wires 302, and the neighboring sub-cathodes 301 in a first row are connected to each other by the metal wires 302, so as to connect each of the sub-cathodes 301 in the cathode layer 1023 to each other and reduce number of signal lines required for inputting signals into the cathode layer.

The substrate in the present preferred embodiment can be a single-crystal silicon substrate or a polycrystalline silicon substrate. The touch array substrate further includes an array circuit layer formed on the substrate. The array circuit layer includes a plurality of thin-film transistors of the substrate, and an active region is formed on the substrate. Since a carrier mobility of the single-crystal silicon can exceed 600 cm²/V-sec, the use of single-crystal silicon to form the active layer can improve the performance of the thin film transistors. Further, a size of the thin film transistor is reduced on a basis of the prior art while ensuring the performance of the thin film transistors, thereby improving an aperture ratio of the touch display substrate.

Further, the light emitting layer of the touch array substrate of the preferred embodiment includes: a hole injection layer, a hole transport layer, an organic light emitting layer, an electron transport layer, and an electron injection layer disposed in sequence and located at a side of the anode layer neighboring the cathode layer.

In the touch array substrate of the present preferred embodiment, an area of the cathode layer is reduced by forming the cathode layer as a structure with a plurality of sub-cathodes which have intervals and are electrically connected to each other, so as to reduce a capacitive load between the cathode layer and a touch sensing layer and improve a touch sensing of the touch panel.

The present disclosure further provides a touch panel including a touch array substrate, a color filter substrate facing to the touch array substrate, and a liquid crystal layer disposed between the touch array substrate and the color filter substrate. A structure of the touch array substrate is the same as a structure of the touch array substrate in the preferred embodiment described above. Specifically, reference will be made to the description of the preferred embodiment of the touch array substrate described above, and will not be described again herein.

In the touch array substrate and the touch panel of the present disclosure, an area of the cathode layer is reduced by forming the cathode layer as a structure with a plurality of sub-cathodes which have intervals and are electrically connected to each other, so as to reduce a capacitive load between the cathode layer and a touch sensing layer and improve a touch sensing of the touch panel.

As described above, although the present disclosure has been described in preferred embodiments, they are not intended to limit the present disclosure. One of ordinary skill in the art, without departing from the spirit and scope of the disclosure within, can make various modifications and variations, so the range of the scope of the disclosure is defined by the claims.

1. A touch array substrate, comprising:
a substrate;
an organic electroluminescent pixel unit layer disposed on the substrate;
wherein the organic electroluminescent pixel unit layer comprises an anode layer, a light emitting layer, and a cathode layer, all of which are stacked in sequence;
wherein the cathode layer consists of a plurality of sub-cathodes disposed at intervals, and the sub-cathodes are electrically connected to each other;
wherein the sub-cathodes are in an array arrangement, and each of the sub-cathodes has a same shape and a same size; and
wherein the sub-cathodes are electrically connected to each other by a plurality of metal wires.

2. The touch array substrate according to claim 1, wherein neighboring sub-cathodes in a same row are electrically connected to each other by the metal wires, and neighboring sub-cathodes in at least one column are electrically connected to each other by the metal wires.

3. The touch array substrate according to claim 1, wherein neighboring sub-cathodes in a same column are electrically connected to each other by the metal wires, and neighboring sub-cathodes in at least one row are electrically connected to each other by the metal wires.

4. The touch array substrate according to claim 1, wherein the substrate is a single-crystal silicon substrate or a polycrystalline silicon substrate.

5. The touch array substrate according to claim 1, wherein the light emitting layer comprises a hole injection layer, a hole transport layer, an organic light emitting layer, an electron transport layer, and an electron injection layer disposed in sequence and located at a side of the anode layer neighboring the cathode layer.

6. The touch array substrate according to claim 1, further comprising a protective layer and a touch sensing layer disposed in sequence and located on the cathode layer, wherein the touch sensing layer comprises a plurality of touch electrodes, and a plurality of touch signal wires, wherein each of the touch signal wires is connected correspondingly with each of the touch electrodes.

7. The touch array substrate according to claim 1, further comprising an array circuit layer formed on the substrate, wherein the array circuit layer comprises a plurality of thin-film transistors, and an active region is formed on the substrate.

8. A touch array substrate, comprising:
a substrate;
an organic electroluminescent pixel unit layer disposed on the substrate;
wherein the organic electroluminescent pixel unit layer comprises an anode layer, a light emitting layer, and a cathode layer, all of which are stacked in sequence; and
wherein the cathode layer consists of a plurality of sub-cathodes disposed at intervals, and the sub-cathodes are electrically connected to each other.

9. The touch array substrate according to claim 8, wherein the sub-cathodes are in an array arrangement, and each of the sub-cathodes has a same shape and a same size.

10. The touch array substrate according to claim 8, wherein the sub-cathodes are electrically connected to each other by a plurality of metal wires.

11. The touch array substrate according to claim 10, wherein neighboring sub-cathodes in a same row are electrically connected to each other by the metal wires, and neighboring sub-cathodes in at least one column are electrically connected to each other by the metal wires.

12. The touch array substrate according to claim 10, wherein neighboring sub-cathodes in a same column are electrically connected to each other by the metal wires, and neighboring sub-cathodes in at least one row are electrically connected to each other by the metal wires.

13. The touch array substrate according to claim 8, wherein the substrate is a single-crystal silicon substrate or a polycrystalline silicon substrate.

14. The touch array substrate according to claim 8, wherein the light emitting layer comprises a hole injection layer, a hole transport layer, an organic light emitting layer, an electron transport layer, and an electron injection layer disposed in sequence and located at a side of the anode layer neighboring the cathode layer.

15. The touch array substrate according to claim 8, further comprising a protective layer and a touch sensing layer disposed in sequence and located on the cathode layer, wherein the touch sensing layer comprises a plurality of touch electrodes, and a plurality of touch signal wires, wherein each of touch signal wires is connected correspondingly with each of the touch electrodes.

16. The touch array substrate according to claim 8, further comprising an array circuit layer formed on the substrate, wherein the array circuit layer comprises a plurality of thin-film transistors, and an active region is formed on the substrate.

17. A touch panel, comprising:
a touch array substrate, comprising:
a substrate;
an organic electroluminescent pixel unit layer disposed on the substrate, wherein the organic electroluminescent pixel unit layer comprises an anode layer, a light emitting layer, and a cathode layer, all of which are stacked in sequence; and
wherein the cathode layer consists of a plurality of sub-cathodes disposed at intervals, and the sub-cathodes are electrically connected to each other.

18. The touch panel according to claim 17, wherein the sub-cathodes are in an array arrangement, and each of the sub-cathodes has a same shape and a same size.

19. The touch panel according to claim 17, wherein the sub-cathodes are electrically connected to each other by a plurality of metal wires.
